(19) United States
(12) Patent Application Publication
(10) Pub. No.: US 2010/0181582 A1
(43) Pub. Date: Jul. 22, 2010

(54) LIGHT EMITTING DEVICES WITH PHOSPHOR WAVELENGTH CONVERSION AND METHODS OF MANUFACTURE THEREOF

(75) Inventors: Yi-Qun Li, Danville, CA (US); Jonathan Melman, San Ramon, CA (US); Ian Collier, Hayward, CA (US)

Correspondence Address: FLIESLER MEYER LLP, 650 CALIFORNIA STREET, 14TH FLOOR, SAN FRANCISCO, CA, 94108, US

(73) Assignee: INTEMATIX CORPORATION, Fremont, CA (US)

(21) Appl. No.: 12/689,449

(22) Filed: Jan. 19, 2010

Related U.S. Application Data
(60) Provisional application No. 61/146,379, filed on Jan. 22, 2009.

(51) Int. Cl. H01L 33/00

(52) U.S. Cl. 257/91; 438/26; 438/27; 438/28; 257/98; 257/E33.056; 257/E33.068

(57) ABSTRACT

A light emitting device comprises: a package (low temperature co-fired ceramic) having a plurality of recesses (cups) in which each recess houses at least one LED chip and at least one phosphor material applied as coating to the light emitting light surface of the LED chips, wherein the phosphor material coating is conformal in form. In another arrangement a light emitting device comprises: a planar substrate (metal core printed circuit board); a plurality of light emitting diode chips mounted on, and electrically connected to, the substrate; a conformal coating of at least one phosphor material on each light emitting diode chip; and a lens formed over each light emitting diode chip.

### CROSS-REFERENCE TO RELATED APPLICATIONS

This application claims the benefit of priority to U.S. Provisional Application No. 61/146,379, filed Jan. 22, 2009, entitled “Light Emitting Device with Phosphor Wavelength Conversion and Methods of Manufacture Thereof” by Yi-Qun Li et al, the specification and drawings of which are incorporated herein by reference.

### BACKGROUND OF THE INVENTION

1. Field of the Invention

The invention relates to light emitting devices with phosphor wavelength conversion and to methods of applying one or more phosphor materials to a light emitting diode (LED) chip. More particularly, although not exclusively, the invention concerns light emitting devices in which the one or more phosphor materials comprise a conformal coating.

2. Description of the Related Art

White light emitting LEDs (“white LEDs”) are known in the art and are a relatively recent innovation. It was not until LEDs emitting in the blue/ultraviolet part of the electromagnetic spectrum were developed that it became practical to develop white light sources based on LEDs. As taught, for example in U.S. Pat. No. 5,998,925, white LEDs include one or more phosphor materials, that is photo-luminescent materials, which absorb a portion of the radiation emitted by the LED and re-emit radiation of a different color (wavelength). Typically, the LED chip generates blue light and the phosphor material(s) absorbs a percentage of the blue light and re-emits yellow light or a combination of green and red light, green and yellow light or yellow and red light. The portion of the blue light generated by the LED that is not absorbed by the phosphor material combined with the light emitted by the phosphor material provides light which appears to the human eye as being nearly white in color.

An example of a typical white LED 10 is shown in FIG. 1 and comprises a blue light emitting GaN (gallium nitride) LED chip 12 housed within a package 14. The package 14, which can for example comprise a low temperature co-fired ceramic (LTCC) or high temperature polymer, comprises upper and lower body parts 16, 18. The upper body part 16 defines a recess or cup 20, often circular in shape, which is configured to receive one or more LED chips 12. The package 14 further comprises electrical connectors 22, 24 that also define corresponding electrode contact pads 26, 28 on the floor of the recess 20. Using adhesive or solder the LED chip 12 is mounted to the floor of the recess 20. The LED chip's electrode pads are electrically connected to corresponding electrode contact pads 26, 28 on the floor of the package using bond wires 30, 32 and the recess 20 is completely filled with a transparent polymer material 34, typically a silicone, which is loaded with the powdered phosphor material(s) such that the exposed surfaces of the LED chip 12 are covered by the phosphor/polymer material mixture. To enhance the emission brightness of the device the walls of the recess are inclined and have a light reflective surface.

A drawback with such devices is that the color hue of light generated by the device, or in the case of a white light emitting device the correlated color temperature (CCT), can vary significantly between devices that are supposed to be nominally the same. The problem of color/CCT variation is compounded by the fact that the human eye is extremely sensitive to subtle changes in color hue especially in the white color range. As is known, the CCT of a white light source is determined by comparing its hue with a theoretical, heated black-body radiator. CCT is specified in Kelvin (K) and corresponds to the temperature of an ideal black-body radiator which radiates the same hue of white light as the light source. The CCT of a white LED is generally determined by the phosphor material composition, the quantity of phosphor material incorporated in the device and its actual location/distribution.

As well as color/CCT variation between devices it is found that the color/CCT can vary across the light emitting surface of the device. The color/CCT depends in part on the thickness of phosphor/polymer and the distance (i.e. path length) that light travels from the LED chip through the phosphor/polymer encapsulation before being emitted from the device. As shown in FIG. 1, light 36 which is emitted on axis (i.e. normal to the light emitting surface of the LED chip) will have traveled a shorter path length 38 within the phosphor/polymer encapsulation than light 40 emitted towards the periphery of the device in which the path length 42 is correspondingly longer (this ignores light scattering and the isotropic nature of phosphor photoluminescence). As a result the light 36 emitted on axis will have a higher proportion of blue light compared to yellow (phosphor generated light) and will appear blue-white in color. Conversely light 40 emitted off axis towards the periphery of the recess will have a correspondingly higher proportion of yellow light emitted by the phosphor material and will appear yellow-white in color. For general lighting applications, where for example a diffuser is used, this variation in color may not be a problem as the lit object itself will also increase illumination color uniformity. However, in applications in which the device includes secondary optical components, in particular a lens, to focus or otherwise direct the output light such color/CCT variation can present a problem. For example for a white LED which includes a lens, the focused light spot will have a blue-white core with a pronounced yellow-white annular periphery. Moreover, the inventors have appreciated that the problem of color variation is compounded by the device's poor approximation to an ideal point source. Typically the recess is a few millimeters (3.5 mm) in dimension as compared to the light emitting surface of the chip which is relatively smaller and may be in a range of a few tens of micrometers (e.g. 50 μm-300 μm) up to one millimeter in size. Once the recess is potted with the phosphor/polymer material mixture the effective light generating area of the device becomes the size of the cup which is comparable to the size of the lens.

In addition to the problem of non-uniformity in emitted color/CCT due to the variation in path length through the phosphor/polymer encapsulation, it is found that the phosphor material(s) can accumulate unevenly during curing of the liquid polymer resulting in a non-uniform distribution of the phosphor material(s) over the LED chip and in particular on the sides of the LED chip, which will also emit light to a lesser extent, where there may be little or no phosphor material(s). As illustrated in FIG. 1 the phosphor material can tend to accumulate/settle on the bond wires 44, on the upper light emitting surface 46 of the LED chip, on the floor 48 of the recess and on the inclined reflecting walls 50 of the package. To overcome this problem a greater quantity of phosphor material is often used though this can result in a corresponding decrease in emitted light intensity. The inventors have appreciated that the variation in color hue can additionally depend on factors including:

variations in bonding wire shape and location which can affect the wetting of the phosphor,

adhesive bleed out which can affect the wetting of the phosphor/polymer mixture,

variations in emission direction of the LED chip,

variations in the reflector (recess) characteristic,

variations or aging in the phosphor/polymer mixture,

wavelength emission distribution of LED chips.

It is believed that all of these factors can affect the color hue/CCT of light generated by a light emitting device with phosphor wavelength conversion.

Various methods of applying the phosphor to the LED chip have been proposed in an effort to improve coating uniformity, color hue and CCT consistency. US 2006/0097621 A1 to Park et al. teaches a method of manufacturing a white LED comprising dispensing droplets of a high viscosity liquid phosphor paste on an upper surface of the LED chip such that the phosphor paste is applied onto the upper surface and side surfaces of the LED chip and then curing the phosphor paste. The phosphor paste comprises a phosphor powder mixed with a transparent polymer resin and has a viscosity of 500˜10,000 cps. The volume of the phosphor paste droplet and viscosity of the phosphor paste are selected such that the phosphor paste covers the upper surface and side surfaces of the LED chip. After application of the phosphor paste the polymer resin is cured and the LED chip is connected to the package using bond wires. Finally the package is filled with a transparent polymer material to protect the bond wires.

As taught in our co-pending U.S. Patent Application Publication No. US 2009/0134414 A1 (Ser. No. 12/239,357, filed Sep. 26, 2008) a method of fabricating a light emitting device comprises: heating a light emitting diode chip package assembly to a pre-selected temperature and dispensing a pre-selected volume of a mixture of at least one phosphor and a light transmissive thermosetting material (silicone, epoxy) on a surface of the chip. The pre-selected volume and temperature are selected such that the phosphor/material mixture flows over the entire light emitting surface of the chip before curing. In an alternative method, using a light transmissive ultraviolet (U.V.) curable material such as an epoxy, the phosphor/material mixture is irradiated with U.V. radiation after a pre-selected time to cure the material. The pre-selected volume and pre-selected time are selected such that the phosphor/material mixture flows over at least the light emitting surface of the chip before curing.

US 2008/0076198 to Park et al. describes a method of manufacturing an LED package comprising: encapsulating an LED chip with a resin and then forming a phosphor thin film on a surface of the resin encapsulation by spray coating a phosphor-containing material on the surface of the resin mold.

U.S. Pat. No. 7,344,952 to Chandra describes testing LED dies (chips) and binning them according to their emission color. The LEDs in a single bin are mounted on a single submount (substrate) to form an array of LEDs. Various thin sheets of a flexible encapsulant (e.g. silicone) containing one or more phosphors are preformed, where each sheet has different color conversion properties. An appropriate sheet is placed over an array of LEDs on a submount, and the LEDs are energized. The CCT of the emitted light is measured. If the CCT is acceptable, the phosphor sheet is permanently laminated onto the LEDs and submount. The LEDs in the array are separated into individual devices. By selecting a different phosphor sheet for each bin of LEDs, the resulting CCT is more consistent across the bins. Although such a process can produce devices with a more consistent CCT, the LED dies and phosphor sheet need to be binned and this can make the process too expensive for many applications.

U.S. Pat. No. 7,049,159 to Lowery describes forming a luminescent layer on light emitting semiconductor devices that are mounted on a substrate. The method comprises positioning a mold on a substrate such that the light emitting semiconductor devices are located within a respective opening of the mold, depositing a molding composition (silicone) including the luminescent material in each opening, removing the mold and then curing the molding composition to a solid state. Finely divided silica is dispersed in the molding composition to form a thixotropic gel such that the molding composition forms a phosphor containing layer that, if undisturbed, retains its shape after the mold has been removed and before the composition is cured. The use of a mold enables luminescent layers to be formed on the light emitting devices without covering adjacent areas of the substrate such as substrate electrical contacts and thus, wire bonding of such contacts can occur subsequent to the formation of the luminescent layers. A disadvantage of the method is that a bulge can form on the upper surface of the device during removal of the mold and this can affect the color uniformity of light emitted by the device. Moreover the emission intensity of the device can be reduced due to absorption by the silica.

US 2006/0284207 A1 to Park et al. teaches applying the phosphor material during formation of the LED package. LED chips are electrically connected to pattern electrodes on a substrate such as a PCB or ceramic substrate. An encapsulant, epoxy molding compound (EMC) containing the phosphor material is formed on each LED chip by transfer (injection) molding. After curing, the encapsulant is cut around the periphery of the chip and a layer of a highly reflective metal is formed on the periphery of the encapsulant by electrolysis, electro-plating or sputtering. The reflective layer defines the side wall of the packaged LED. Finally, the substrate is cut horizontally and vertically into individual LED packages.

In our co-pending U.S. Patent Application Publication No. US 2009/0101930 A1 (Ser. No. 11/906,545 filed Oct. 1, 2007) a method of fabricating a light emitting device having a specific target color of emitted light is described. The method comprises: depositing a pre-selected quantity of at least one phosphor material on a light emitting surface of a light emitting diode; operating the light emitting diode; measuring the color of light emitted by the device; comparing the measured color with the specific target color; and depositing and/or removing phosphor material to attain the desired target color.

A need exists still for light emitting devices with phosphor wavelength conversion that can produce a more consistent color/CCT and are less expensive to manufacture than the prior art solutions.

### SUMMARY OF THE INVENTION

The present invention arose in an endeavor to address the problem of color hue and/or CCT variation of light emitting devices that include phosphor wavelength conversion. Embodiments of the invention are directed to light emitting devices in which the one or more phosphor materials comprise a substantially conformal coating on the LED chip. Moreover, the invention concerns methods of applying the phosphor material coating to LED chips.

According to the invention a light emitting device comprises: a package having a plurality of light reflective recesses (cups) in which each recess houses at least one light emitting diode chip; and at least one phosphor material applied as coating to the light emitting surface of the light emitting diode chips, wherein the phosphor material coating is conformal in form. Preferably the package comprises a high temperature polymer package, a ceramic package or a low temperature co-fired ceramic package. Applying the one or more phosphor materials as a substantially conformal coating on the LED chip provides a number of benefits compared with potting the recess with a phosphor encapsulation, these being: i) the device is a closer approximation to a point light source which can simplify the secondary optics required to focus or otherwise direct the light emission of the device, ii) an improvement in the uniformity of the color/CCT of light emission from the device due to a reduction in the light path difference between the center and edges of the LED chip and iii) an increase in light output due to the closer proximity of the phosphor with the LED chip.

Typically the phosphor coating is of a thickness in a range 20 μm to 200 μm and comprises a mixture of at least one phosphor material and a light transmissive (transparent) material such as a polymer material typically a silicone or an epoxy. The weight loading of the at least one phosphor material to polymer material is typically in a range 50 to 99 parts per 100. The inventors have discovered surprisingly that to optimize the light output intensity of the device for a given color/CCT and given mass of phosphor material the thickness of the phosphor coating should be as thin as possible whilst the loading of phosphor to polymer material should be as high as possible. To promote the emission of light from the device the wall of each recess is preferably inclined and includes a light reflective surface such as a metallization layer of for example silver, aluminum or chromium.

Each LED chip is mounted on, and electrically connected to contact pads on, the floor of the recess before applying the conformal coating of phosphor. Typically the depth of each recess results in the upper light emitting surface of the LED chip being below the face of the package requiring a special method of applying a phosphor conformal coating over the light emitting surface and edges of the LED chip. According to a first method of the invention a method of manufacturing such a device comprises a mold having a plurality of projections that are configured to fit into a respective recess wherein each projection has an aperture configured to surround the respective at least one light emitting diode chip, the method comprising: a) positioning the mold on the package such that each aperture overlies a respective light emitting diode chip; b) filling each cell with a pre-selected volume of a mixture of at least one phosphor material and a light transmissive polymer material; c) at least partially curing the polymer material; and d) removing the mold.

To eliminate the need to measure preselected volumes of the phosphor/polymer mixture the method can further comprise an insert having a plurality of projections that are configured to fit in a respective aperture of the mold and to limit the volume of each aperture to a preselected volume, the method further comprising inserting the insert in the mold, filling each aperture with the phosphor/polymer mixture and removing the mold insert such as to allow the phosphor/polymer mixture to drain from the insert into its respective aperture. The apertures can conveniently be filled by sweeping the phosphor/polymer mixture over the surface of the insert and then removing excess phosphor/polymer mixture using a flexible blade, doctor blade, squeegee or other similar device or method.

To enable fast and accurate relative positioning of the mold and package, the mold preferably further comprises features for cooperating with the recesses. In one arrangement the features comprise fins that extend radially from one or more of the projections wherein the fins are configured to enable the mold to be accurately positioned relative to the package. The fins are preferably tapered with a taper that is complementary with the inclined walls of the recess.

To aid in the removal of the mold and/or insert, the mold and/or insert preferably includes a coating of, or is fabricated from, a “non-stick” material such as PTFE (polytetrafluoroethylene) for example Teflon® (“Teflon” is a registered trademark of Du Pont). Alternatively and/or in addition, a release agent can be applied to the surfaces of the mold and/or insert, by for example spraying, to assist in their clean release. Since the light transmissive polymer material will often be a silicone material which is hydrophobic the release agent is preferably hydrophilic such as a polyvinyl alcohol (PVA) to prevent adhesion of the polymer material to the mold and/or insert. Moreover, the mold and/or insert can be resiliently deformable to thereby aid removal of the mold and/or insert. The mold and/or insert can comprise a metal (for example stainless steel), a glass, a polymer, a polycarbonate, an acrylic, a silicone or an epoxy.

The polymer material which typically comprises a silicone or an epoxy can be thermally or U.V. curable. Where the polymer material is thermally curable the mold/package assembly can be heated by placing the assembly in a heated environment. It is also envisaged to incorporate one or more electrical heating elements in the mold. Where the material is U.V. curable the mold is preferably fabricated from a material which is substantially transmissive to U.V. radiation and the phosphor/polymer mixture irradiated with U.V. radiation through the mold.

To reduce the formation of air bubbles or voids in the phosphor/polymer coating any of the steps of mixing, dispensing and curing the phosphor/polymer mixture are preferably carried out in a reduced pressure atmosphere or under a partial vacuum.

According to a second aspect of the invention a light emitting device comprises a substantially planar substrate; a plurality of light emitting diode chips mounted on, and electrically connected to, the substrate; a conformal coating of at least one phosphor material on each light emitting diode chip; and a lens formed over each light emitting diode chip. Typically the substrate can comprise a metal core printed circuit board (MCPCB), a printed circuit board or a ceramic circuit board. As with the device in accordance with the first aspect of the invention, the phosphor coating typically has a thickness in a range 20 μm to 200 μm and comprises a mixture of at least one phosphor material and a light transmissive material such as a polymer material in which the weight loading of the at least one phosphor material is in a range 50 to 99 parts per 100 parts of polymer material.

According to the invention a method of manufacturing the device in accordance with the second aspect of the invention comprises: a) mounting the plurality of light emitting diode chips on the substrate; b) providing a first mold having a respective aperture corresponding to each light emitting diode chip; c) positioning the first mold on the substrate such that each aperture overlies a respective light emitting diode chip; d) filling each cell with a mixture of the at least one phosphor material and a light transmissive polymer material; e) at least partially curing the polymer; f) removing the first mold; g) providing a second mold having a respective open cell corresponding to each light emitting diode chip, each cell being configured in the form of a lens; h) filling each cell with a light transmissive polymer material; i) positioning the substrate on the second mold such that each light emitting diode chip is located within a respective cell; j) at least partially curing the light transmissive polymer material; and k) removing the second mold.

Preferably the method further comprises applying a release agent, such as a polyvinyl alcohol or other hydrophilic material, to surfaces of the first and/or second molds.

To further aid in the release of the molds, the first and/or second molds can comprise a coating of or be fabricated from a non-stick material such as PTFE. Additionally, the first and/or second molds are resiliently deformable to thereby aid in their removal.

Typically the polymer material can be a silicone or an epoxy that is thermally or U.V. curable. Where the polymer material is thermally curable the first and/or second mold can be heated to at least partially cure the polymer material. In one arrangement the first and/or second mold can incorporate one or more heating elements such as electrical heating elements. Where the material is U.V. curable the first and/or second molds can comprise a material which is substantially transmissive to U.V. radiation and the polymer material is irradiated with U.V. radiation through the first and/or second molds.

The first and/or second molds can comprise a metal such as stainless steel, a glass, a polymer, a polycarbonate, an acrylic, a silicone, an epoxy or PTFE.

Preferably the substrate and first and/or second molds comprise inter-cooperating features such as pegs/holes for relatively aligning the first and/or second molds on the substrate.

To reduce the formation of air bubbles or voids in the phosphor/polymer coating and/or in the lenses, any of the steps of mixing, dispensing and curing the phosphor/polymer mixture and/or dispensing and curing the light transmissive polymer are preferably carried out in a reduced pressure atmosphere or under a partial vacuum.

It is envisaged in yet a further arrangement to use a single mold to form the phosphor encapsulation and define an array of lenses. In such an arrangement the mold is a single-use item that is left in situ to become the array of lenses. According to this embodiment of the invention there is provided a method of manufacturing the device in accordance with the second aspect of the invention that comprises a light transmissive cover having on a first face a respective lens corresponding to each light emitting diode chip and on an opposite planar face an open cell corresponding to each light emitting diode chip, the method comprising: a) mounting the plurality of light emitting diode chips on the substrate; b) filling each cell with a mixture of the at least one phosphor material and a light transmissive polymer material; c) positioning the substrate on the mold such that each light emitting diode chip is within a respective cell; and d) at least partially curing the polymer material. The cells can conveniently be filled by sweeping the phosphor/polymer mixture over the surface of the insert and then removing excess phosphor/polymer mixture using a flexible blade, doctor blade, squeegee or similar device.

### BRIEF DESCRIPTION OF THE DRAWINGS

In order that the present invention is better understood embodiments of the invention will now be described, by way of example only, with reference to the accompanying drawings in which:

FIG. 1 is a schematic sectional view of a known light emitting device with phosphor wavelength conversion as previously described;

FIG. 2 is a schematic sectional representation of a light emitting device in accordance with a first embodiment of the invention;

FIG. 3 is a schematic perspective representation of a mold used in a first method of the invention to apply a phosphor material coating to the light emitting device of FIG. 2;

FIGS. 4(a) to 4(e) are schematic representations of method steps for applying the phosphor material to the light emitting device of FIG. 2 according to the first method of the invention;

FIGS. 5(a) to 5(f) are schematic representations of method steps for applying the phosphor material to the light emitting device of FIG. 2 according to a second method of the invention;

FIG. 6 is a schematic sectional representation of a light emitting device in accordance with a second embodiment of the invention;

FIGS. 7(a) to 7(h) are schematic representations of method steps for applying the phosphor material to the light emitting device of FIG. 6 according to a third method of the invention;

FIG. 8 is a schematic sectional representation of a light emitting device in accordance with a third embodiment of the invention;

FIG. 9 is a schematic sectional representation of a mold/cover used to apply a phosphor material to the light emitting device of FIG. 8; and

FIGS. 10(a) to 10(d) are schematic representations of method steps for applying the phosphor material to the light emitting device of FIG. 8 according to a fourth method of the invention.

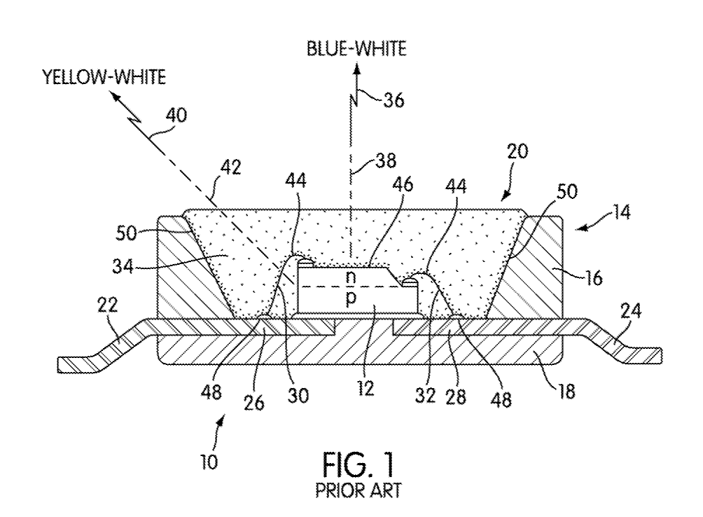

### DETAILED DESCRIPTION OF THE INVENTION

Embodiments of the invention concern light emitting devices with phosphor wavelength conversion and methods of applying one or more phosphor materials to an LED chip to form a coating of a preselected form, typically a conformal coating. In this specification like reference numerals are used to denote like parts.

### 1^{st} Embodiment

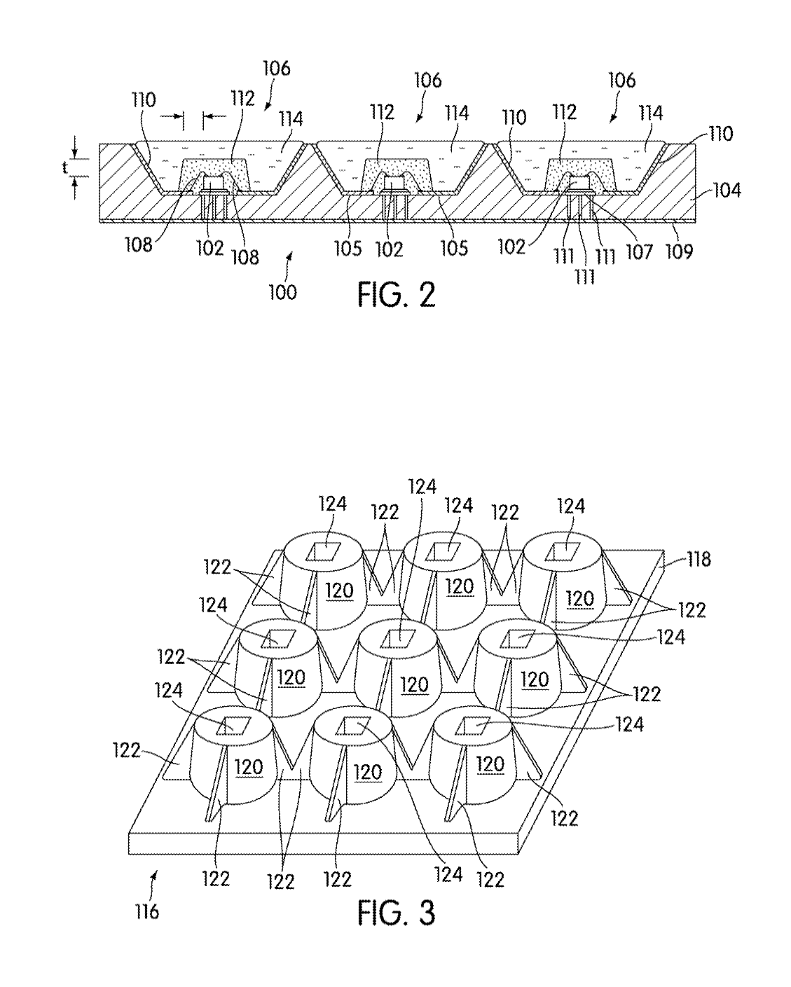

FIG. 2 is a schematic sectional view of a white light emitting device 100 in accordance with a first embodiment of the invention. The device 100 comprises an array of blue (i.e. dominant wavelength in a range ≈400 to 480 nm) surface emitting InGaN/GaN (indium gallium nitride/gallium nitride) based light emitting diode (LED) chips 102 packaged in a high temperature package 104 such as for example a low temperature co-fired ceramic (LTCC) package of a type as described in co-pending U.S. Patent Application Publication No. 2009/0294780 A1 (Ser. No. 12/127,749 filed May 27, 2008) the specification and drawings of which are incorporated herein by reference. In FIG. 2 the device 100 comprises a square array of nine LED chips 102 (3 rows by 3 columns), though it will be appreciated that the device of the invention applies to other LED chip configurations that can comprise many more LED chips. The package 104 has in an upper surface a square array of circular recesses (cups) 106 each of which is configured to receive a respective LED chip 102. The package 104 further comprises electrical connectors that define corresponding electrode contact pads 105 on the floor of each recess 106. Each LED chip 102 is mounted to the floor of a respective recess 106 using for example a thermally conductive adhesive or eutectic soldering. Electrode pads on the upper surface of the LED chip 102 are electrically connected to a corresponding electrode contact pad 105 on the floor of the package by bond wires 108. To aid in heat dissipation the floor of each recess can include a thermally conducting mounting pad 107 on which the LED chip is mounted using a thermally conductive adhesive or soldering. The thermally conducting mounting pad 107 is thermally connected with a corresponding mounting pad 109 on the base of the package by an array of thermally conducting vias 111. As an example each recess 106 can be ≈4 mm in diameter with a spacing between recess centers of ≈6 mm. Typically, each LED chip 102 is square in form with a side length of ≈200 μm. The wall of each recess 106 is inclined and includes a light reflective surface 110 such as a metallization layer of silver, aluminum or chromium.

Each LED chip 102 is encapsulated with a conformal coating 112 that comprises a mixture of one or more phosphor materials and a light transmissive (transparent) binder material, typically a polymer such as a silicone or an epoxy. The thickness “t” (measured from the upper surface and edges of the LED chip) of the phosphor/polymer coating 112 is of order ≈20 to ≈200 μm, typically approximately 100 μm. The required thickness “t” of the phosphor/polymer layer 112 will depend on the target color/CCT of light generated by the device. Moreover the thickness “t” will depend on the weight loading of the phosphor to polymer. The weight loading of the at least one phosphor material to polymer material is typically in a range 50 to 99 parts per 100. The inventors have discovered that the light output increases with decreasing thickness “t” and hence in general for a given target color/CCT and mass of phosphor material the thickness of the phosphor coating should be as thin as possible whilst the loading of phosphor to polymer material should be as high as possible.

Advantageously, the light transmissive polymer is selected such that its refractive index is as close to the refractive index of the LED chips 102 as practicable. For example, the refractive index of an InGaN/GaN LED chip is n≈2.4 to 2.5 whilst a high refractive index silicone has a refractive index n≈1.2 to 1.5. Thus in practice the polymer material has a refractive index ≧1.2. The use of a high refractive index polymer can increase emission of light from the LED chips 102 by providing a degree of refractive index matching and reducing light reflection at the interface between the LED chip and phosphor/polymer coating.

Optionally each recess 106 can be filled with a light transmissive (transparent) polymer material 114, typically a silicone, to provide environmental protection of the phosphor/polymer encapsulation 112.

1^{st} Method

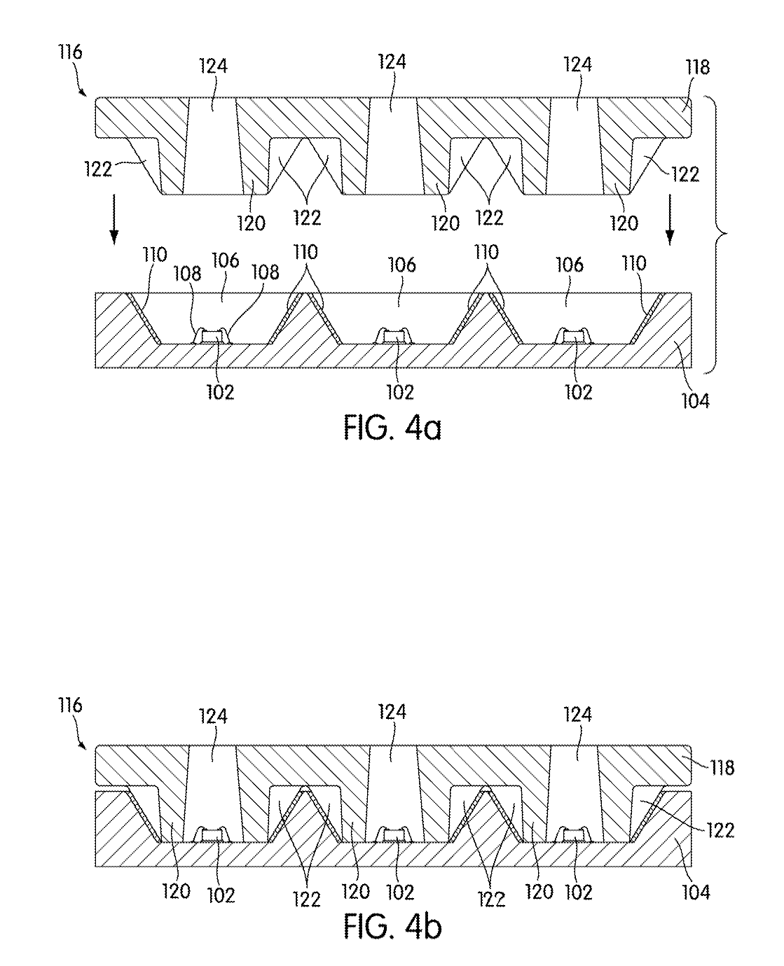

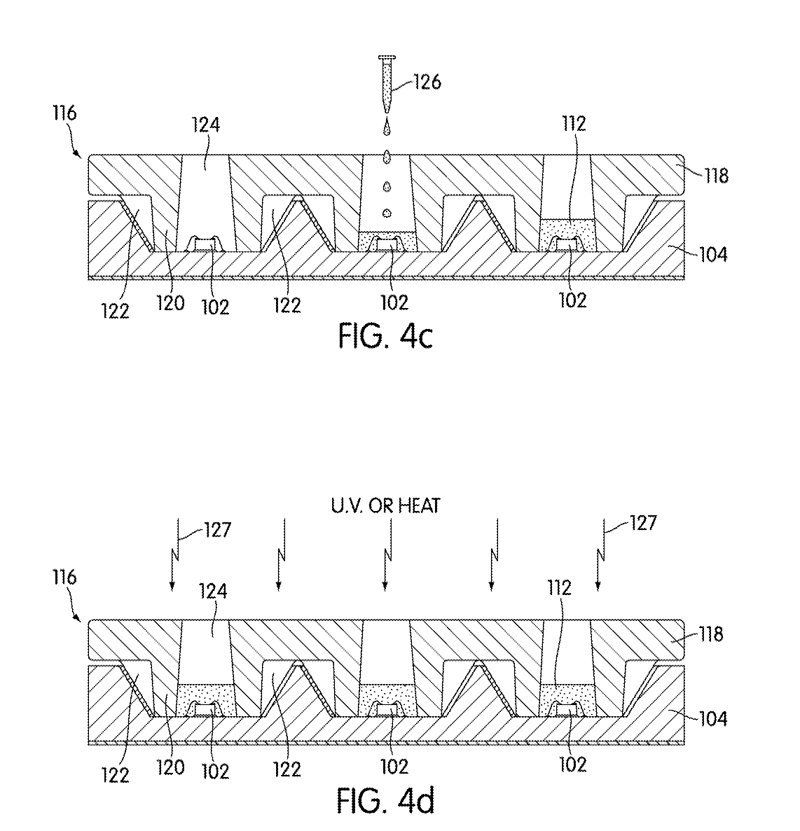

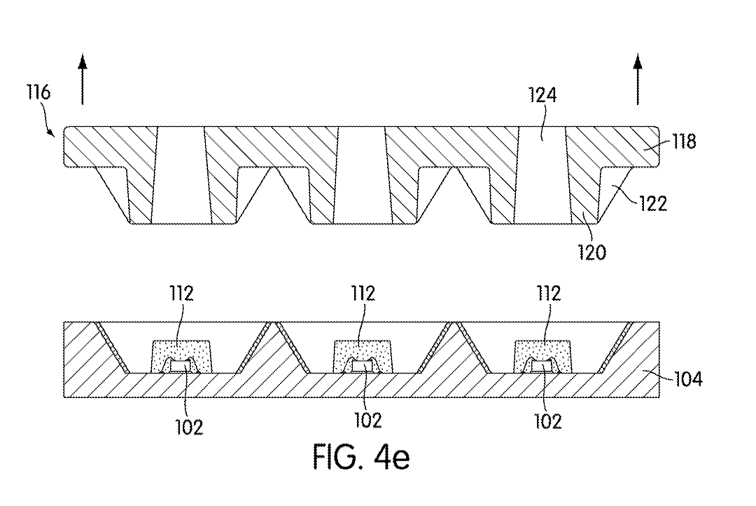

A method in accordance with a first embodiment of the invention for forming the phosphor/polymer encapsulation 112 of the white light emitting device 100 of FIG. 2 will now be described in relation to FIG. 3 and FIGS. 4a to 4e.

FIG. 3 is a perspective schematic representation of a mold (template or stencil) 116 used in the method of the invention to form the conformal phosphor/polymer coating 112 over each LED chip 102. For ease of understanding the mold 116 is illustrated in an inverted orientation in FIG. 3 with the upper surfaces being those which will engage with the floor of the recesses 106 of the package 104 during operation. The mold 116 comprises a plate 118 with a square array of generally cylindrical projections 120 that are configured such that each projection corresponds to a respective recess 106 of the package 104. The projections 120 are positioned and dimensioned such that they will fit into a respective recess of the package. As illustrated each projection 120 can further include four circumferentially equally spaced radially extending tapered fins (ribs) 122 on its exterior surface. As will be described the fins 122 are configured to aid in the rapid and accurate positioning (aligning) of the mold 116 on the package 104. It will be appreciated that the form factor of the fins does not have to exactly match the corresponding recess in order to provide an aligning function. In other embodiments fewer or more fins or other features can be used to accurately align the mold.

Each projection 120 includes an aperture (through hole) 124 that passes through the entire thickness of the mold 116 and as will be further described each aperture 124 comprises a cell that is used to mold the phosphor/polymer over the exterior surfaces of an associated LED chip 102 in a preselected form, i.e. as a conformal coating. The apertures 124 are configured such that when the mold is mounted on the package each aperture surrounds an associated LED chip 102. As is best seen in FIG. 4a each aperture 124 preferably tapers inwardly towards the plate 118 (i.e. the rear of the mold) to aid in the subsequent removal of the mold. For illustrative purposes the angle of taper is exaggerated in the accompanying drawings. The mold 116 can comprise for example a metal such as stainless steel, a polymer material such as a polycarbonate, an acrylic, a silicone or an epoxy or a glass. Preferably the mold further comprises a coating of, or is fabricated from, a non-stick material such as PTFE (polytetrafluoroethylene) for example Teflon® (“Teflon” is a registered trademark of Du Pont) to aid in the removal of the mold. Moreover, the mold can be resiliently deformable to assist in its removal.

Step 1—FIGS. 4a and 4b: Each LED chip 102 is mounted to the floor of a respective recess 106 of the package 104 and each electrode pad of the LED chip 102 electrically connected to its corresponding electrode contact pad on the floor of the package by bond wires 108. Optionally and to aid in the subsequent release of the mold 116 the surfaces of the mold, namely the surfaces of each cell 124 and the outer surfaces of each projection 120, are coated (by for example spraying) with a release agent. The release agent can comprise a commercially available release agent such as Stoner E218 or a hydrophilic material such as a water soluble polyvinyl alcohol (PVA) since this will prevent adhesion of the silicone encapsulant which is hydrophobic. The mold 116 is positioned over the package 104 and brought into engagement with the package such that the end face of each projection engages with the floor of its associated recess 106. The fins 122 enable rapid and accurate alignment of the mold 116 on the package 104.

Step 2—FIG. 4c: A phosphor (photoluminescent) material, which is in powder form, is thoroughly mixed in pre-selected proportions with a light transmissive (transparent) liquid polymer material such as for example a transparent silicone or epoxy. The liquid polymer material can be thermally curable or U.V. curable. In this implementation the polymer material is a thermally curable material such as for example GE's silicone RTV615. The weight loading of phosphor to silicone is typically in a range 50 to 99 parts per 100 parts of silicone with the exact loading depending on the required color/CCT of the emission product of the device. A pre-selected volume of the liquid phosphor/polymer mixture 126 is dispensed into each aperture 124 using for example a nano-liter plunger type dispenser made by Asymtek. As can be seen in FIG. 4c the preselected volume of phosphor/polymer mixture is selected such that phosphor/polymer 122 forms a conformal layer over the entire light emitting surface (i.e. upper surface as shown) of the LED chip 102 and also the edges of the LED chip that will also emit light to a lesser extent. For example for a ≈200 μm square LED chip of thickness ≈200 μm, ≈70 nano-liters (nl) of the liquid phosphor/polymer mixture are required for a ≈100 μm thickness “t” conformal coating. It will be appreciated that the volume of phosphor/polymer mixture dispensed in each aperture will depend on the dimensions of the aperture and the required thickness of the phosphor/polymer coating.

Step 3—FIG. 4d: With the mold 116 in situ on the package the polymer material is at least partially cured by for example placing the mold/package 116/104 assembly in a temperature controlled environment or by heating the mold 116. In the case of the latter it is envisaged for the mold to incorporate one or more heating elements such as electrical heating elements. In the case where the polymer material cures at room temperature the partial curing can be achieved by waiting a pre-selected period of time and it will be appreciated therefore that the invention applies to both actively and passively curing the polymer material. Alternatively, where the polymer material is U.V. curable, the polymer material can be cured by exposing the mold/package assembly to U.V. radiation 127. In either case the polymer material has to be cured sufficiently such that the phosphor coating will retain its shape when the mold 116 is subsequently removed.

Step 4—FIG. 4e: Once the polymer has at least been partially cured the mold 116 is physically removed to leave each LED chip 102 with a phosphor/polymer conformal coating 112. Optionally each recess 106 is then filled with a light transmissive (transparent) polymer material 114, typically a silicone, to provide environmental protection of the phosphor/polymer encapsulation 112.

To reduce the formation of air bubbles or voids in the phosphor/polymer encapsulation 112 and/or light transmissive encapsulation 114, the steps of mixing, dispensing and curing (i.e. steps 1 to 3) the phosphor/polymer mixture and/or dispensing the light transmissive polymer can be carried out in a reduced pressure atmosphere or under a partial vacuum.

2^{nd} Method

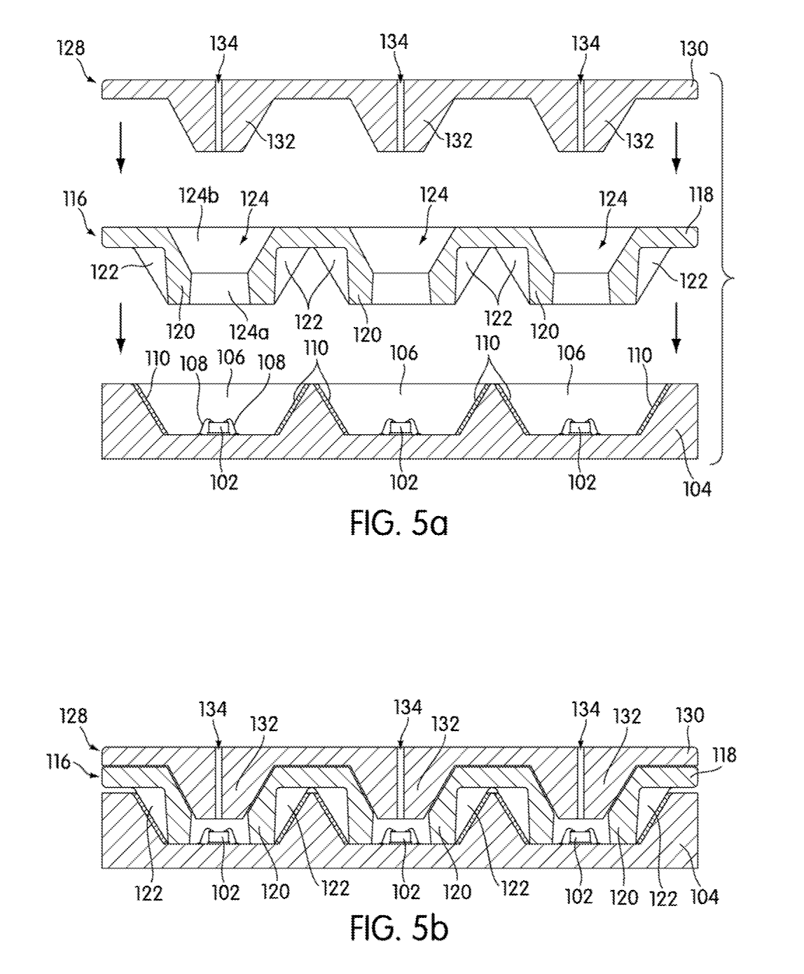

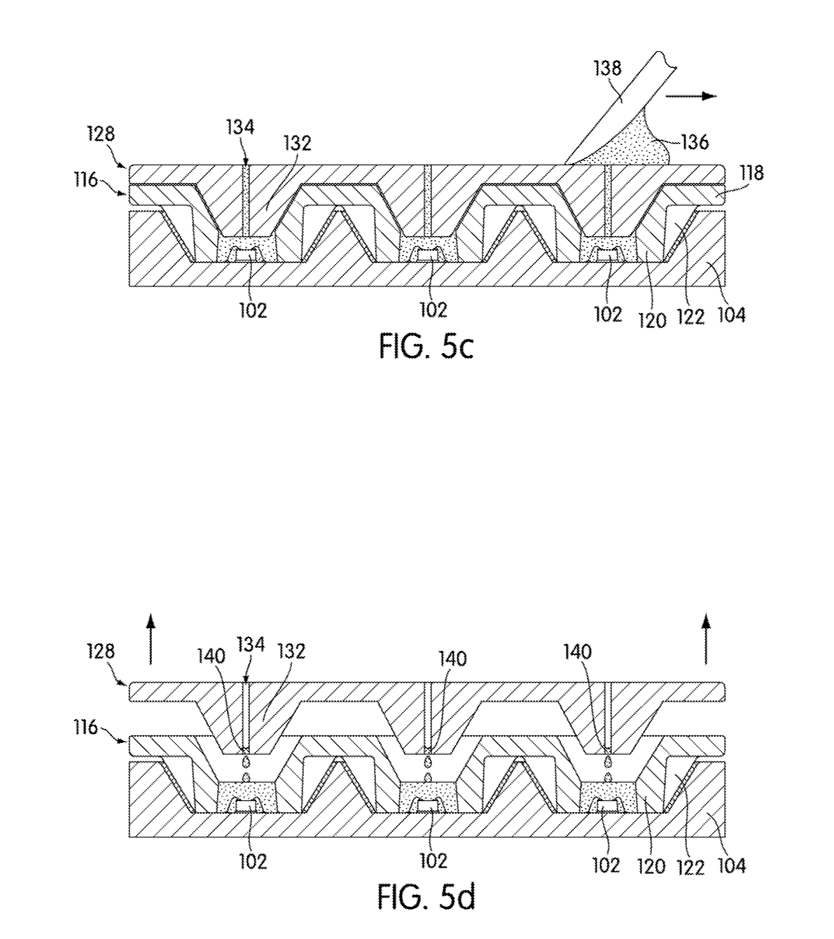

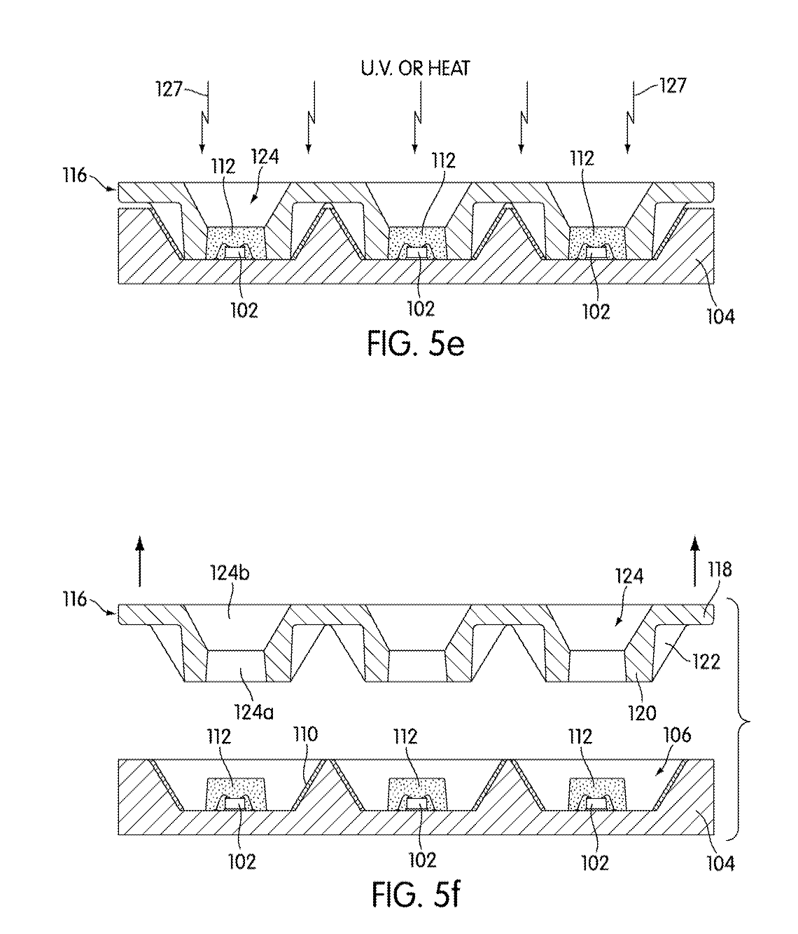

A method in accordance with a second embodiment of the invention for forming the phosphor/polymer encapsulation 112 of the white light emitting device 100 of FIG. 2 will now be described in relation to FIGS. 5a to 5f. In this embodiment a mold insert 128 is used to limit the volume of each aperture (cell) 124 of the mold to a preselected volume and to thereby eliminate the need to individually dispense a preselected volume of the phosphor/polymer material in each aperture 124.

As is best seen in FIG. 5a the mold 116 has the same general form as in the first embodiment except that each aperture 124 now comprises lower 124a and upper 124b portions of different form. The lower portion 124a of each aperture has an opening in the end face of the projection 120 and is configured to define the conformal coating of phosphor on each LED chip. To aid in the removal of the mold 116 the lower portion 124a can be slightly inwardly tapered in a direction towards the plate 118. Conversely, the upper portion 124b of each aperture has an opening in the face of the plate 118 and is configured to receive the mold insert 130. In the example illustrated the upper portion 124b of each aperture is square in form and tapers outwardly towards the face of the plate.

The mold insert 130 comprises a plate 132 with a square array of square tapered projections 134 (i.e. truncated square pyramids). The projections 134 are configured such that each will fit into the upper portion 124b of a respective aperture 124 and limit the volume of the lower portion 124a of the aperture to a selected volume. Each projection 134 includes a respective filling hole 134 that passes through the entire thickness of the insert 128 to enable each aperture 124 to be filled with the phosphor/polymer material 126 from the planar face of the insert. The projections 134 are configured such that when the insert 128 is mounted on the mold 116 the combined volume of each lower portion 124a of the aperture 124 and the filling hole 134 corresponds to the preselected volume required to form the conformal coating. The insert 128 can comprise for example a metal such as stainless steel, a polymer material such as a polycarbonate, an acrylic, a silicone or an epoxy or a glass. Preferably the insert further comprises a coating of, or is fabricated from, a non-stick material such as PTFE (polytetrafluoroethylene) for example Teflon® to aid in the removal of the insert.

Step 1—FIGS. 5a and 5b: Each LED chip 102 is mounted to the floor of a respective recess 106 of the package 104 and each electrode pad of the LED chip 102 electrically connected to its corresponding electrode contact pad on the floor of the package by bond wires 108. Optionally and to aid in the subsequent release of the mold 116 and insert 128, the surfaces of mold 116 and mold insert 128 are coated with a release agent such as a PVA. The mold 116 is positioned over the package 104 and brought into engagement with the package such that the end face of each projection 120 engages with the floor of its associated recess 106. The fins 122 enable rapid and accurate alignment of the mold 116. The insert 128 is then mounted to the mold such that each projection 132 of the mold insert 128 fits into corresponding aperture 124 of the mold. It will be appreciated that the insert 128 can alternatively be inserted in the mold and the mold/insert assembly then mounted to the package.

Step 2—FIG. 5c: Each of the apertures 124 and the filling holes 134 are filled with a liquid phosphor/polymer mixture 136. Since the surface of the insert 128 is planar the apertures 124 can conveniently be filled by sweeping the phosphor/polymer mixture over the upper surface of the insert of then removing excess phosphor/polymer by passing a doctor blade or squeegee 138 or like device.

Step 3—FIG. 5d: The insert 128 is then carefully removed such as to allow the liquid phosphor/polymer material 140 within the filling holes 134 to drain into its respective aperture 124 and the phosphor/polymer material allowed to settle.

Step 4—FIG. 5e: Before removal of the mold 116 the polymer material is at least partially cured by for example placing the mold/package 116/104 assembly in a temperature controlled environment or by heating the mold 116. Where the polymer material is U.V. curable, the polymer material can be cured by exposing the mold/package assembly to U.V. radiation 127.

Step 5—FIG. 5f: Once the polymer has at least been partially cured the mold 116 is physically removed to leave each LED chip 102 with a phosphor/polymer conformal coating 112. Optionally each recess 106 is then filled with a light transmissive (transparent) polymer material 114, typically a silicone, to provide environmental protection of the phosphor/polymer encapsulation 112.

To reduce the formation of air bubbles or voids in the phosphor/polymer encapsulation 112, the steps of mixing, dispensing and curing (i.e. steps 1 to 4) the phosphor/polymer mixture can be carried out in a reduced pressure atmosphere or under a partial vacuum.

### 2^{nd} Embodiment

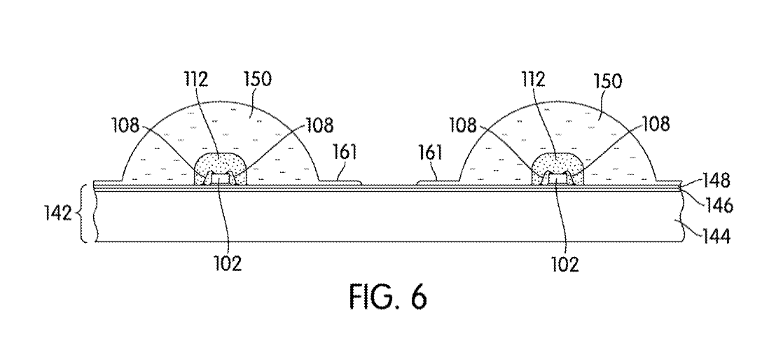

FIG. 6 is a schematic sectional representation of a light emitting device 100 in accordance with a second embodiment of the invention. In this embodiment an array of blue (i.e. wavelength≈400 to 480 nm) surface emitting InGaN/GaN (indium gallium nitride/gallium nitride) based light emitting diode (LED) chips 102 is mounted on a substantially planar substrate 142 such as for example a metal core printed circuit board (MCPCB)—a so called chip on board (COB) arrangement. As is known MCPCBs are commonly used for mounting electrical components that generate large amounts of heat and comprise a layered structure comprising a thermally conducting base 144, typically a metal such as aluminum (Al), and alternating layers of an electrically non-conducting/thermally conducting dielectric material 146 and electrically conducting tracks 148, typically made of copper (Cu). The dielectric layers 146 are very thin such that they can conduct heat from components mounted on the electrical tracks to the base 144. The electrically conducting tracks 148 are configured to define an electrical circuit for providing electrical power to the array of LED chips 102.

In FIG. 6 only two LED chips 102 are shown and in practice the device will often comprise many tens of LED chips that can be arranged in various configurations such as linear, square or hexagonal arrays. In other arrangements it is envisaged that the substrate 142 can comprise a printed circuit board such as an FR-4 (fire retardant 4) printed circuit board or a ceramic circuit board. The electrically conducting tracks 148 further define electrode contact pads for electrical connection to a corresponding electrode contact pad on the LED chip by bond wires 108. Each LED chip 102 is encapsulated with a phosphor/polymer encapsulation 112 that is conformal in form which in turn is encapsulated with a hemispherical lens 150.

3^{rd} Method

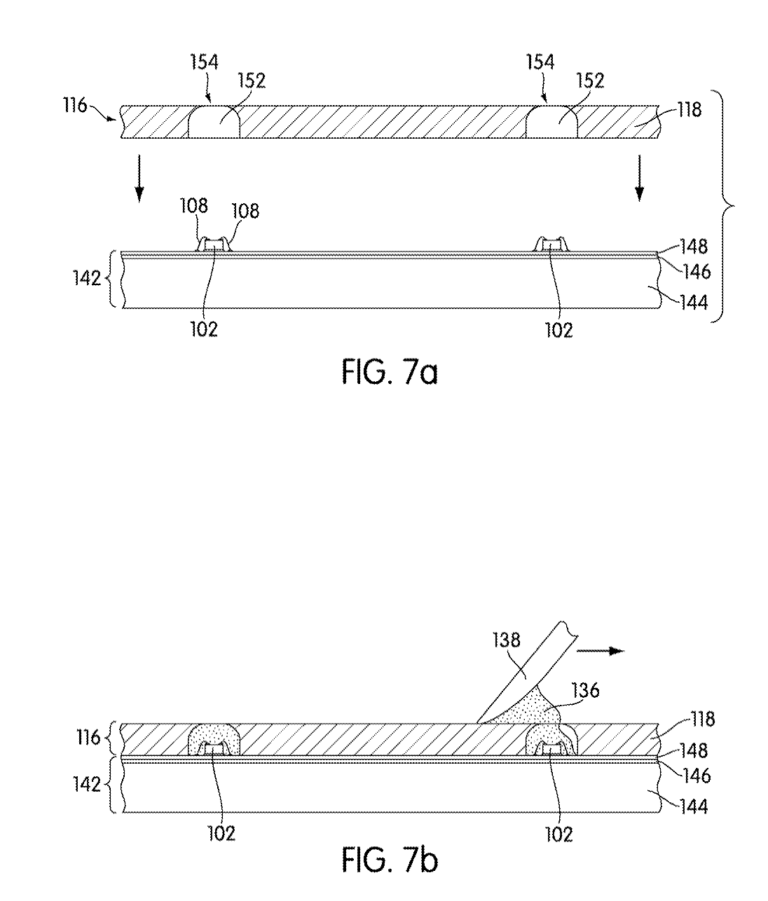

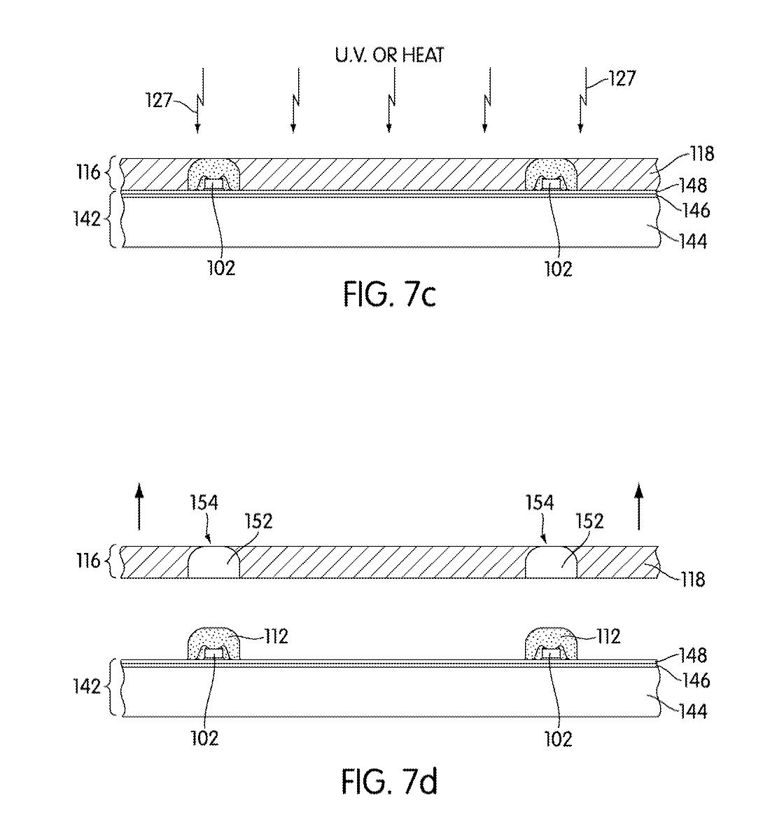

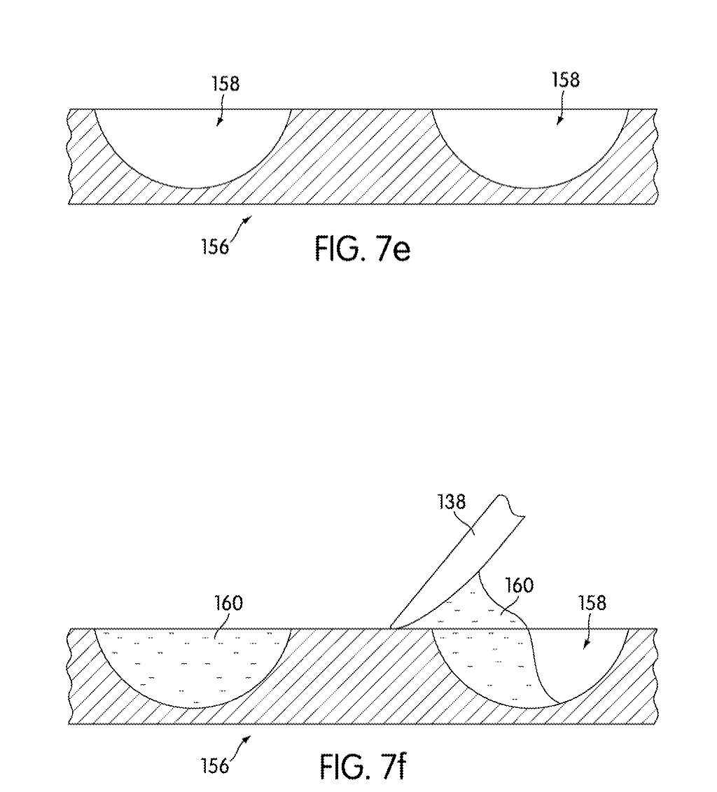

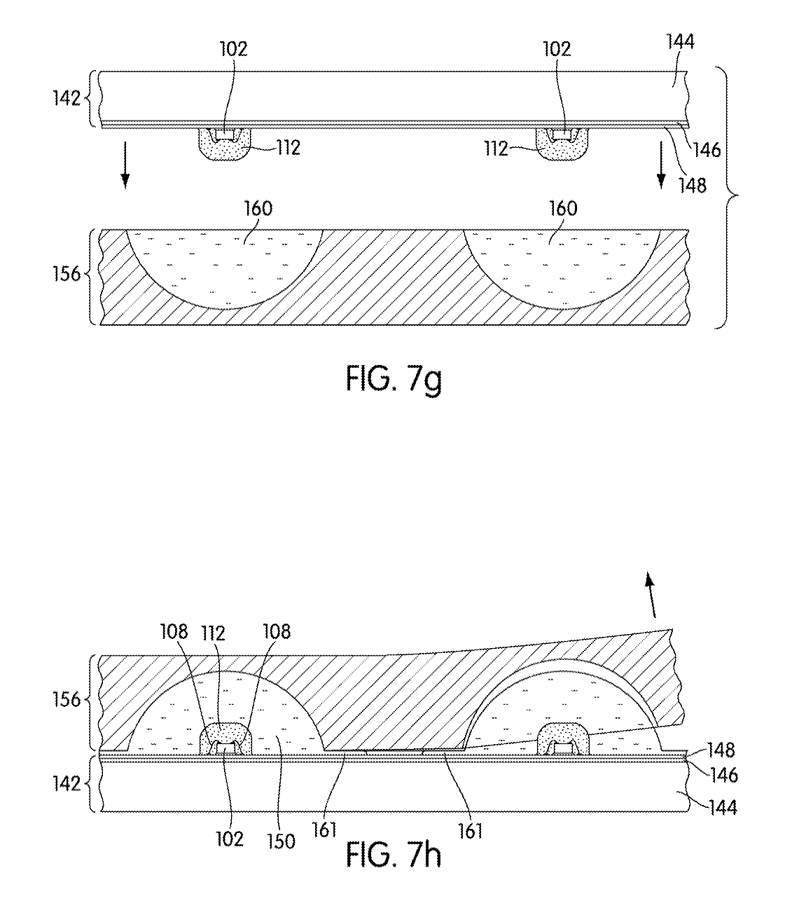

A method in accordance with a third embodiment of the invention for forming the phosphor/polymer encapsulation 112 and lenses 150 of the white light emitting device 100 of FIG. 6 will now be described in relation to FIGS. 7a to 7h. In this embodiment a first mold 116 is used to form the phosphor encapsulation and a second mold 156 is used to form the array of lenses 150. As illustrated in FIG. 7a the first mold 116 comprises a plate 118 with an array of apertures (cells) 152 that are configured such that each aperture 152 corresponds to a respective LED chip 102. The base of each aperture 152 includes an opening 154 that passes through the thickness of the mold 116 and enables the aperture to be filled with the phosphor/polymer mixture. It will be appreciated that the apertures 152 are configured such that when the first mold is appropriately positioned on the substrate 142 each is centered on, and surrounds, an associated LED chip 102. In this embodiment the thickness of the first mold 116 corresponds to the combined height of the LED chip and thickness “t” of the phosphor coating. To enable rapid and accurate positioning of the first mold 116 on the substrate 124 the mold/substrate can further comprise cooperating alignment features such as posts/holes (not shown). In operation, and as illustrated in FIG. 7a, the mold is oriented such that the openings face in an upward direction.

Step 1—FIG. 7a: Each LED chip 102 is mounted to the substrate 124 and the electrode pads of the LED chips 102 are electrically connected to their corresponding electrode contact pads on the substrate by bond wires 108. Optionally, the surfaces of the first mold 116, namely the surfaces of each aperture 152 and the lower face (i.e. the face that faces the substrate in operation), are coated with a release agent. The first mold 116 is positioned over the substrate 142 with each aperture overlying a respective LED chip and brought into engagement with the substrate such that the face of the first mold 116 including the aperture openings engages with the face of the substrate.

Step 2—FIG. 7b: Each of the apertures 152 is filled with a liquid phosphor/polymer mixture 136 through the openings 154 by sweeping the phosphor/polymer mixture across the upper surface of the first mold and then removing excess phosphor/polymer mixture using a doctor blade, squeegee or alike 138.

Step 3—FIG. 7c: With the first mold 116 in situ the polymer material is then at least partially cured by for example heating or exposing the polymer material to U.V. radiation 142 through the mold. The polymer material has to be cured sufficiently such that the phosphor coating 112 will retain its shape when the mold is removed.

Step 4—FIG. 7d: having at least partially cured the polymer material the first mold 116 is physically removed to leave each LED chip 102 with a phosphor/polymer coating 112 that is substantially conformal in form.

Step 5—FIG. 7e: The second (lens) mold 156 used to form the lenses 150 comprises on a planar face an array of open generally hemispherical shaped cells 158 that are configured such that each cell 158 corresponds to a respective LED chip 102. The second mold 156 can comprise a metal such as stainless steel, a polymer material such as for example an acrylic, a silicone or an epoxy or a glass. Preferably the mold further comprises a coating of, or is fabricated from, a non-stick material such as PTFE.

Step 6—FIG. 7f: Optionally and to aid in the subsequent release of the lens mold 156, the surfaces of the lens mold are coated with a release agent. Each cell 158 of the lens mold 156 is filled with a light transmissive (transparent) liquid lens material 160 such as for example a polymer material, such as a silicone or epoxy material, by sweeping the lens material 160 over the upper planar face of the mold and removing excess lens material using a doctor blade or squeegee or alike 138. To maximize light emission of the device the lens material 160 is selected such that its refractive index is as close to the refractive index of the phosphor/polymer encapsulation 112 as possible to provide a degree of index matching between the phosphor encapsulation and lens 150. Thus in practice the lens material is typically the same as the polymer material used in the phosphor/polymer encapsulation. To further assist in the coupling of light from the phosphor/polymer encapsulation 112 into the lens 150 it is envisaged to texture the surface (i.e. a surface topology) of the phosphor/polymer encapsulation 112 with a surface roughening or surface patterning. In the case of the latter the surface of the apertures 152 of the first mold can incorporate a surface patterning.

Step 8—FIG. 7g: The substrate 142 is positioned over the lens mold 150 with the face of the substrate carrying the LED chips 102 facing the surface of the mold such that each LED chip overlies and is centered on a corresponding cell 158. The substrate is brought into engagement with the face of the mold 150 such that each LED chip is fully encapsulated by the lens material 160. The lens material is then at least partially cured.

Step 9—FIG. 7h: The completed device 100 is physically removed from the lens mold 156. As illustrated in FIG. 7h the lens mold 150 can be resiliently deformable to assist in the release of the lens mold.

As best seen in FIG. 6 each phosphor encapsulated LED chip will displace a corresponding volume of lens material 161 that will accumulate on the surface of the substrate 142 around each lens. It is found that such material 161 does not significantly affect the optical performance of the device since there is little or no light emission in this region. To reduce the formation of air bubbles or voids in the phosphor/polymer encapsulation and/or in the lenses 150, any of the steps of mixing, dispensing or curing (i.e. steps 1 to 3) the phosphor/polymer mixture and/or dispensing or curing the transparent lens material (i.e. steps 7 and 8) can be carried out in a reduced pressure atmosphere or under a partial vacuum.

### 3^{rd} Embodiment

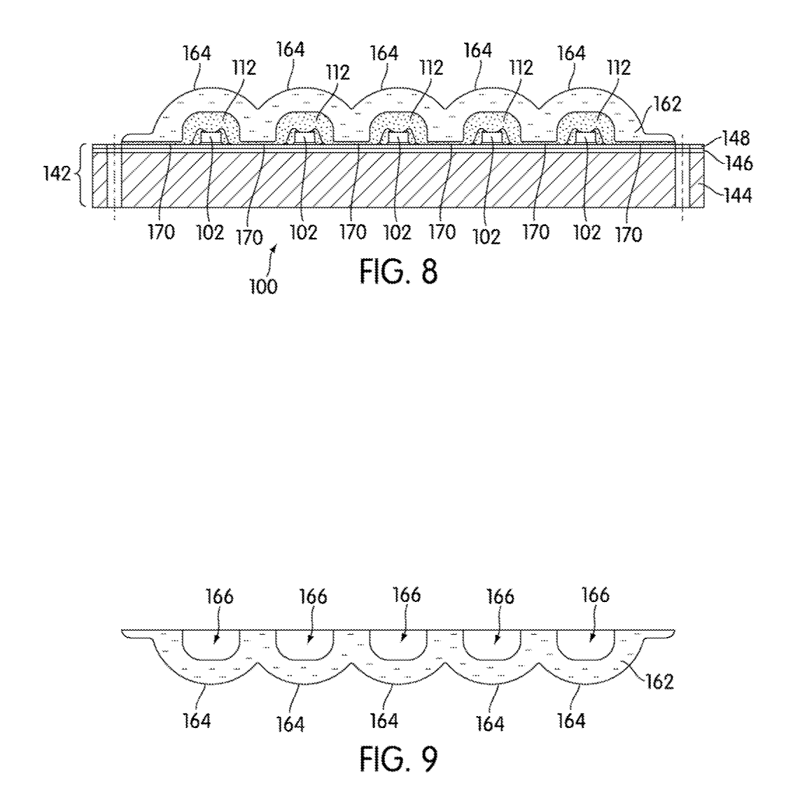

FIG. 8 is a schematic sectional representation of a light emitting device 100 in accordance with a third embodiment of the invention. In this embodiment an array of surface emitting InGaN/GaN based light emitting diode (LED) chips 102 are mounted on a planar substrate 142 such as for example a printed circuit board, MCPCB or ceramic circuit board. Each LED chip 102 is encapsulated with a phosphor coating 112 that is substantially conformal in form and the phosphor coating is itself encapsulated within a light transmissive (transparent) cover 162 that provides environmental protection of the phosphor encapsulation 112. The transparent cover 162 further defines a respective lens element 164 corresponding to each LED chip 102 for focusing or otherwise directing light emission from the device. As will be described the transparent cover 162 is used to mold the phosphor encapsulation 112 and is left in situ. Due to the dual function of the cover 162, that is as both a mold and as a cover, it will hereinafter be referred to as a “mold/cover”.

4^{th} Method

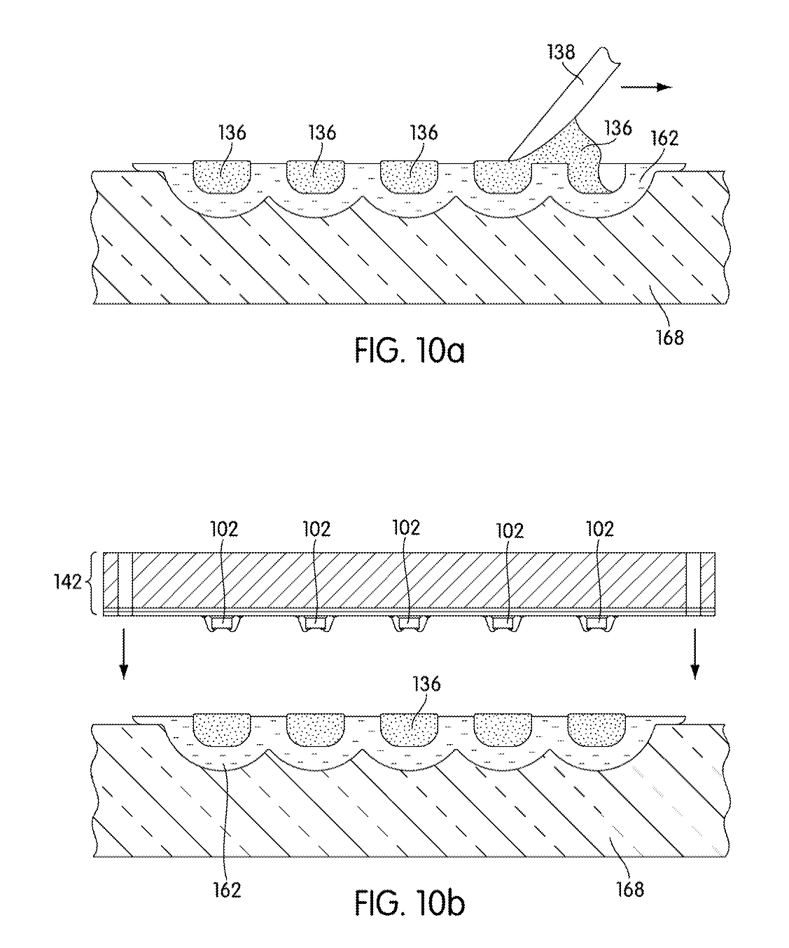

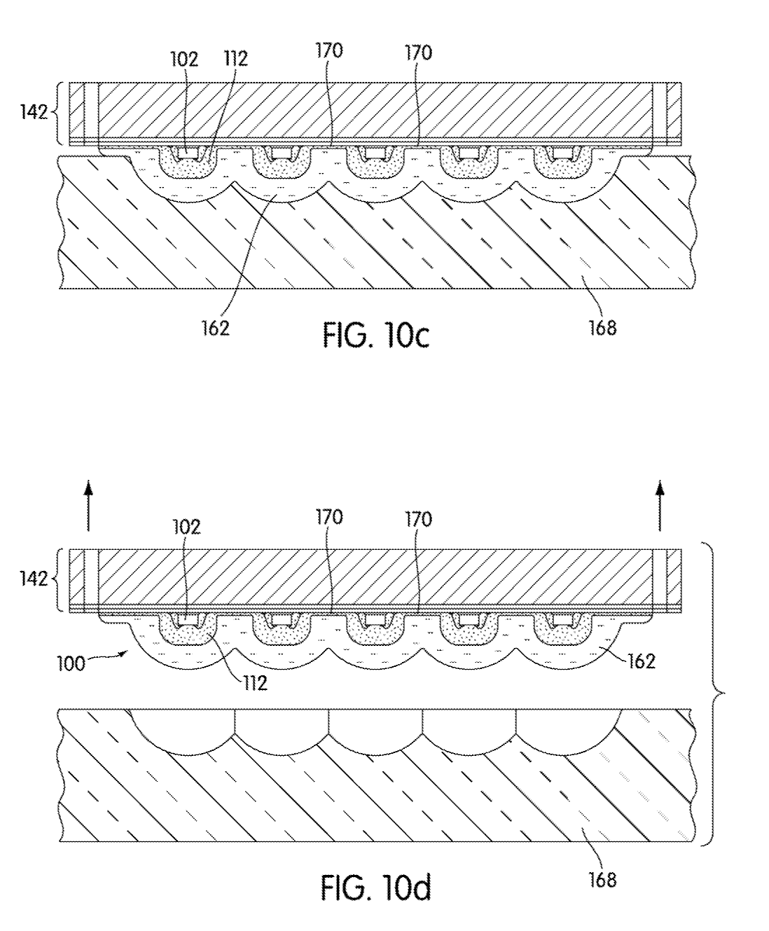

A method in accordance with a fourth embodiment of the invention for forming the phosphor/polymer encapsulation 112 of the white light emitting device 100 of FIG. 8 will now be described in relation to FIGS. 9 and 10a to 10d. In this embodiment the mold/cover 162 is a single-use item. FIG. 9 is a schematic sectional representation of the mold/cover 162 and comprises on a planar face an array of open shaped cells 166 that are configured such that each cell 166 corresponds to a respective LED chip 102. Each 166 cell is configured such as to form a substantially conformal coating of phosphor over its respective LED chip 102. The opposite face of the mold/cover 162 is configured to define an array of lens elements 164. The mold/cover 162 comprises a light transmissive material such as a silicone, acrylic or polycarbonate. To maximize light emission from the device, the mold/cover 162 comprises a material whose refractive index is as close to the refractive index of the phosphor/polymer coating 112 as practicable to provide a degree of index matching between the phosphor encapsulation 112 and the mold/cover 162. Thus in practice the mold/cover material can be the same as the transparent polymer used in the phosphor/polymer encapsulation. To further assist in coupling light from the phosphor/polymer encapsulation 112 to the mold/cover 162 the surface of each cell 166 can be textured with for example a surface roughening or regular patterning.

Step 1—FIG. 10a: With the mold/cover 162 supported in a complementary shaped support member 168, each of the cells 166 is filled with a phosphor/polymer mixture 136. Since the upper face (i.e. the face containing the cells) of the mold/cover is planar in form the cells 166 can conveniently be filled by sweeping the phosphor/polymer mixture 136 over the upper surface of the cover/mold and then removing excess phosphor/polymer mixture using a doctor blade, squeegee or alike 138.

Step 2—FIGS. 10b and 10c: Each LED chip 102 is mounted to the substrate 142 and each electrode pad of the LED chip 102 electrically connected to its corresponding electrode contact pad on the substrate by bond wires 108. The substrate 124 is positioned over the mold/cover 162 with the face of the substrate carrying the LED chips 102 facing the surface of the cover/mold. The substrate is positioned such that each LED chip 102 overlies and is centered on a corresponding cell 166 and the substrate is brought into engagement with the face of the cover/mold. The polymer material is then at least partially cured.

Step 3—FIG. 10d: The completed device 100 is physically removed from the support member 168.

As best seen in FIG. 8 each LED chip 102 will displace a corresponding volume of phosphor/polymer material 170 that will accumulate on the interface between the substrate 142 and cover/mold 162. It is found that such material 170 has little or no effect on the optical performance of the device, in particular the color and/or CCT of emitted light, since there is minimal light in this region of the device. A particular benefit of using a transparent cover both to mold the phosphor encapsulation and to act as an array of lenses is that this eliminates the need to remove and/or clean the mold making manufacture of the device quicker and cheaper. It is believed that the use of a transparent cover including an array of lenses or other optical components to mold the phosphor encapsulation is inventive in its own right.

The methods of the invention are suitable for applying phosphor material(s) in a powder form which can comprise an inorganic or organic phosphor such as for example silicate-based phosphor of a general composition A₃Si(O,D)₅ or A₂Si(O,D)₄ in which Si is silicon, O is oxygen, A comprises strontium (Sr), barium (Ba), magnesium (Mg) or calcium (Ca) and D comprises chlorine (Cl), fluorine (F), nitrogen (N) or sulfur (S). Examples of silicate-based phosphors are disclosed in our co-pending U.S. patent application publication No. US 2007/0029526 A1 and U.S. Pat. Nos. 7,311,858 B2, 7,575,697 B2 and 7,601,276 B2 (all assigned to Intematix Corporation) the content of each of which is hereby incorporated by way of reference thereto.

As taught in U.S. Pat. No. 7,575,697 B2, a europium (Eu²⁺) activated silicate-based green phosphor has the general formula (Sr,A₁)ₓ(Si,A₂)(O,A₃)₂₊ₓ:Eu²⁺ in which: A₁ is at least one of a 2⁺ cation, a combination of 1⁺ and 3⁺ cations such as for example Mg, Ca, Ba, zinc (Zn), sodium (Na), lithium (Li), bismuth (Bi), yttrium (Y) or cerium (Ce); A₂ is a 3⁺, 4⁺ or 5⁺ cation such as for example boron (B), aluminum (Al), gallium (Ga), carbon (C), germanium (Ge), N or phosphorus (P); and A₃ is a 1⁻, 2⁻ or 3⁻ anion such as for example F, Cl, bromine (Br), N or S. The formula is written to indicate that the A₁ cation replaces Sr; the A₂ cation replaces Si and the A₃ anion replaces oxygen. The value of x is an integer or non-integer between 1.5 and 2.5.

U.S. Pat. No. 7,311,858 B2 discloses a silicate-based yellow-green phosphor having a formula A₂SiO₄:Eu²⁺ D, where A is at least one of a divalent metal comprising Sr, Ca, Ba, Mg, Zn or cadmium (Cd); and D is a dopant comprising F, Cl, Br, iodine (I), P, S and N. The dopant D can be present in the phosphor in an amount ranging from about 0.01 to 20 mole percent and at least some of the dopant substitutes for oxygen anions to become incorporated into the crystal lattice of the phosphor. The phosphor can comprise (Sr_{1-x-y}BaₓM_{y})SiO₄:Eu²⁺ in which M comprises Ca, Mg, Zn or Cd and where 0≦x≦1 and 0≦y≦1.

U.S. Pat. No. 7,601,276 B2 teaches a two phase silicate-based phosphor having a first phase with a crystal structure substantially the same as that of (M1)₂SiO₄; and a second phase with a crystal structure substantially the same as that of (M2)₃SiO₅ in which M1 and M2 each comprise Sr, Ba, Mg, Ca or Zn. At least one phase is activated with divalent europium (Eu²⁺) and at least one of the phases contains a dopant D comprising F, Cl, Br, S or N. It is believed that at least some of the dopant atoms are located on oxygen atom lattice sites of the host silicate crystal.

US 2007/0029526 A1 discloses a silicate-based orange phosphor having the formula (Sr₁₋ₓMₓ)_{y}Eu_{z}SiO₅ in which M is at least one of a divalent metal comprising Ba, Mg, Ca or Zn; 0<x<0.5; 2.6<y<3.3; and 0.001<z<0.5. The phosphor is configured to emit visible light having a peak emission wavelength greater than about 565 nm.

The phosphor can also comprise an aluminate-based material such as is taught in our co-pending U.S. Patent Application Publication No. US 2006/0158090 A1 and U.S. Pat. No. 7,390,437 B2 (also assigned to Intematix Corporation) or an aluminum-silicate phosphor as taught in co-pending application US 2008/0111472 A1 the content of each of which is hereby incorporated by way of reference thereto.

US 2006/0158090 A1 to Wang et al. teach an aluminate-based green phosphor of formula M₁₋ₓEuₓAl_{y}O_{[1+3y/2]} in which M is at least one of a divalent metal comprising Ba, Sr, Ca, Mg, manganese (Mn), Zn, copper (Cu), Cd, samarium (Sm) or thulium (Tm) and in which 0.1≦x≦0.9 and 0.5≦y≦12.

U.S. Pat. No. 7,390,437 B2 discloses an aluminate-based blue phosphor having the formula (M₁₋ₓEuₓ)_{2-z}Mg_{z}Al_{y}O_{[2+3y/2]} in which M is at least one of a divalent metal of Ba or Sr. In one composition the phosphor is configured to absorb radiation in a wavelength ranging from about 280 nm to 420 nm, and to emit visible light having a wavelength ranging from about 420 nm to 560 nm and 0.05<x<0.5 or 0.2<x<0.5; 3≦y≦12 and 0.8≦z≦1.2. The phosphor can be further doped with a halogen dopant H such as Cl, Br or I and be of general composition (M₁₋ₓEuₓ)_{2-z}Mg_{z}Al_{y}O_{[2+3y/2]}:H.

US 2008/0111472 A1 to Liu et al. teach an aluminum-silicate orange-red phosphor with mixed divalent and trivalent cations of general formula (Sr_{1-x-y}MₓT_{y})₃₋ₘEuₘ(Si_{1-z}Al_{z})O₅ in which M is at least one divalent metal selected from Ba, Mg or Ca in an amount ranging from 0≦x≦0.4; T is a trivalent metal selected from Y, lanthanum (La), Ce, praseodymium (Pr), neodymium (Nd), promethium (Pm), Sm, gadolinium (Gd), terbium (Tb), dysprosium (Dy), holmium (Ho), Erbium (Er), Tm, ytterbium (Yt), lutetium (Lu), thorium (Th), protactinium (Pa) or uranium (U) in an amount ranging from 0≦y≦0.4 and z and m are in a range 0≦z≦0.2 and 0.001≦m≦0.5. The phosphor is configured such that the halogen resides on oxygen lattice sites within the silicate crystal.

The phosphor can also comprise a nitride-based red phosphor material such as is taught in our co-pending U.S. Provisional Patent Applications 61/054,399 filed May 19, 2008 entitled “Nitridosilicate-based red phosphors” and 61/122,569 filed Dec. 15, 2008 entitled “Nitride-based red phosphors”, the content of each of which is hereby incorporated by way of reference thereto. 61/054,399 and 61/122,569 teach nitride-based red phosphor having the formula MₘMₐM_{b}D_{3w}N_{[(2/3)m+z+a+(4/3)b-w]}Zₓ where Mₘ is a divalent element selected from beryllium (Be), Mg, Ca, Sr, Ba, Zn, Cd or mercury (Hg); Mₐ is a trivalent element selected from B, Al, Ga, indium (In), Y, selenium (Se), P, arsenic (As), La, Sm, antimony (Sb) or Bi; M_{b} is a tetravalent element selected from C, Si, Ge, tin (Sn), Ni, hafnium (Hf), molybdenum (Mo), tungsten (W), chromium (Cr), lead (Pb), titanium (Ti) or zirconium (Zr); D is a halogen selected from F, Cl, Br or I; Z is an activator selected from europium (Eu), Ce, manganese (Mn), Tb or samarium (Sm), and N is nitrogen in amounts 0.01≦m≦1.5, 0.01≦a≦1.5, 0.01≦b≦1.5, 0.0001≦w≦0.6 and 0.0001≦z≦0.5. The phosphor is configured to emit visible light with an emission peak wavelength greater than 640 nm.

It will be appreciated that the phosphor material is not limited to the examples described herein and can comprise any phosphor material including both organic or inorganic phosphor materials such as for example nitride and/or sulfate phosphor materials, oxy-nitrides and oxy-sulfate phosphors or garnet materials (YAG).

It will be further appreciated that the present invention is not restricted to the specific embodiments described and that variations can be made that are within the scope of the invention. For example, devices in accordance with the invention can comprise other LED chips such as silicon carbide (SiC), zinc selenide (ZnSe), indium gallium nitride (InGaN), aluminum nitride (AlN) or aluminum gallium nitride (AlGaN) based LED chips that emit blue or U.V. light.

Moreover it is also envisaged that the mold or stencil can be a single-use item. Such a mold or stencil can be fabricated from a dissolvable material such as a water soluble poly vinyl alcohol (PVA) and can be removed by dissolving the mold in a suitable solvent such as for example water. A further advantage of using PVA is that it is hydrophilic whilst the silicone encapsulant/lens material is hydrophobic and this can prevent adhesion of the silicone to the mold. It is envisaged that a dissolvable mold will find application for devices where the preselected form of the phosphor material encapsulation and/or lens would otherwise prevent physical removal of the mold such as for example an encapsulation or lens that is part spherical in form.

As described and to enable fast and accurate relative positioning of the mold and substrate, the mold/substrate preferably include inter-cooperating features such as projections (posts or pegs) and indentations (holes). Other methods of accurately positioning the mold will be apparent to those skilled in the art and can include for example aligning visual index markings.

What is claimed is:

1. A light emitting device comprising:
a) a package having a plurality of light reflective recesses in which each recess houses at least one light emitting diode chip and
b) at least one phosphor material applied as coating to the light emitting surface of the light emitting diode chips, wherein the phosphor material coating is conformal in form.

2. The device according to claim 1, wherein the package is selected from the group consisting of: a high temperature polymer package, a ceramic package and a low temperature co-fired ceramic package.

3. The device according to claim 1, wherein the wall of each recess is inclined such as to promote the emission of light from the device.

4. The device according to claim 1, wherein the phosphor coating is of a thickness in a range 20 μm to 200 μm.

5. The device according to claim 1, wherein the phosphor coating comprises a mixture of at least one phosphor material and a light transmissive polymer material and wherein a weight loading of the at least one phosphor material to polymer material is in a range 50 to 99 parts per 100.

6. A method of manufacturing the device according to claim 1 comprising:
a mold having a plurality of projections that are configured to fit into a respective recess wherein each projection has an aperture configured to surround the respective at least one light emitting diode chip, the method comprising:
a) positioning the mold on the package such that each aperture overlies a respective light emitting diode chip;
b) filling each cell with a pre-selected volume of a mixture of at least one phosphor material and a light transmissive polymer material;
c) at least partially curing the polymer material; and
d) removing the mold.

7. The method according to claim 6, and further comprising an insert having a plurality of projections that are configured to fit in a respective aperture of the mold and to limit the volume of each aperture to a preselected volume, the method further comprising inserting the insert in the mold, filling each aperture with the phosphor/polymer mixture and removing the mold insert such as to allow the phosphor/polymer mixture to drain from the insert into its respective aperture.

8. The method according to claim 6, wherein the mold further comprises radial fins extending from one or more of the projections, the fins being configured to enable the mold to be accurately positioned relative to the package.

9. The method according to claim 6, and further comprising applying a release agent to surfaces of the mold and/or insert.

10. The method according to claim 9, wherein the release agent is selected from the group consisting of a hydrophilic material and a polyvinyl alcohol.

11. The method according to claim 1, wherein the polymer material is thermally curable and comprising in c) heating the mold and/or mold/package assembly.

12. The method according to claim 6, wherein the polymer material is ultraviolet curable and the mold comprises a material which is substantially transmissive to ultraviolet radiation and comprising in c) irradiating the phosphor/polymer mixture with ultraviolet radiation through the mold.

13. The method according to claim 6, wherein the mold comprises a material selected from the group consisting of: a metal, a glass, a polymer, a polycarbonate, an acrylic, a silicone, an epoxy and PTFE.

14. A light emitting device comprising:
(a) a substantially planar substrate;
(b) a plurality of light emitting diode chips mounted on, and electrically connected to, the substrate;
(c) a conformal coating of at least one phosphor material on each light emitting diode chip; and
(d) a lens formed over each light emitting diode chip.

15. The device according to claim 14, wherein the substrate is selected from the group consisting of: a metal core printed circuit board, a printed circuit board and a ceramic circuit board.

16. The device according to claim 14, wherein the phosphor coating is of a thickness in a range 20 μm to 200 μm.

17. The device according to claim 14, wherein the phosphor coating comprises a mixture of at least one phosphor material and a light transmissive polymer material and wherein a weight loading of the at least one phosphor material to polymer material is in a range 50 to 99 parts per 100.

18. A method of manufacturing the device according to claim 14 comprising:
a) mounting the plurality of light emitting diode chips on the substrate;
b) providing a first mold having a respective aperture corresponding to each light emitting diode chip;
c) positioning the first mold on the substrate such that each aperture overlies a respective light emitting diode chip;
d) filling each cell with a mixture of the at least one phosphor material and a light transmissive polymer material;
e) at least partially curing the polymer;
f) removing the first mold;
g) providing a second mold having a respective open cell corresponding to each light emitting diode chip, each cell being configured in the form of a lens;
h) filling each cell with a light transmissive polymer material;
i) positioning the substrate on the second mold such that each light emitting diode chip is located within a respective cell;
j) at least partially curing the light transmissive polymer material;
k) removing the second mold.

19. The method according to claim 18, and further comprising applying a release agent to surfaces of the first and/or second molds.

20. The method according to claim 19, wherein the release agent is selected from the group consisting of a hydrophilic material and a polyvinyl alcohol.

21. The method according to claim 18, wherein the first and/or second molds further comprise a coating of non-stick material.

22. The method according to claim 21, wherein the non-stick material comprises a PTFE.

23. The method according to claim 18, wherein the polymer material is thermally curable and comprising heating the first and/or second molds.

24. The method according to claim 18, wherein the polymer material is ultraviolet curable and the first and/or second molds comprise a material which is substantially transmissive to ultraviolet radiation and comprising in e) and/or j) irradiating the polymer mixture with ultraviolet radiation through the first and/or second mold.

25. The method according to claim 18, wherein the first and/or second mold is resiliently deformable to thereby aid its removal.

26. The method according to claim 18, wherein the first and/or second molds comprise a material selected from the group consisting of a metal, a glass, a polymer, a polycarbonate, an acrylic, a silicone, an epoxy and PTFE.

27. The method according to claim 18, wherein the polymer material is selected from the group consisting of: silicone and an epoxy.

28. The method according to claim 18, and further comprising inter-cooperating features on the substrate and first and/or second molds for positioning the molds on the substrate.

29. A method of manufacturing the device according to claim 14 comprising a light transmissive cover having on a first face a respective lens corresponding to each light emitting diode chip and on an opposite planar face an open cell corresponding to each light emitting diode chip, the method comprising:
a) mounting a plurality of light emitting diode chips on the substrate;
b) filling each cell with a mixture of the at least one phosphor material and a light transmissive polymer material;
c) positioning the substrate on the mold such that each light emitting diode chip is within a respective cell; and
d) at least partially curing the polymer material.
